(19) United States
(12) Patent Application Publication
(10) Pub. No.: US 2026/0104367 A1
(43) Pub. Date: Apr. 16, 2026

(54) X-RAY ANALYSIS SYSTEM

(71) Applicant: HONDA MOTOR CO., LTD., Tokyo (JP)

(72) Inventor: Atsushi SAKURAI, Saitama (JP)

(21) Appl. No.: 19/315,669

(22) Filed: Sep. 1, 2025

(30) Foreign Application Priority Data
Oct. 10, 2024 (JP) 2024-178308

(51) Int. Cl. G01N 23/083; G01R 31/387; H01M 10/42

(52) U.S. Cl. CPC G01N 23/083; G01R 31/387; H01M 10/4285; G01N 2223/611

(57) ABSTRACT

An X-ray analysis system irradiates, with an X-ray, a battery cell including a battery and a laminate housing the battery to obtain analysis data. The X-ray analysis system includes a sample holder that can restrain the battery cell, a holder that holds the sample holder and can switch an irradiation position indicating a position to be irradiated with the X-ray, with respect to the battery cell restrained by the sample holder, and a charger-discharger that charges and discharge the battery cell restrained by the sample holder. The sample holder includes a transmissive portion that allows the X-ray to be transmitted through a plurality points of the battery cell.

This application is based on and claims the benefit of priority from Japanese Patent Application No. 2024-178308, filed on 10 October 2024, the content of which is incorporated herein by reference.

### BACKGROUND OF THE INVENTION

### Field of the Invention

The present invention relates to an X-ray analysis system.

### Related Art

X-ray analysis is known as a technique for observing an electrode state of a secondary battery module. The electrode state is, for example, a state of charge (SOC) indicating a state of charge. X-ray analysis is a technique enabling observation of an electrode state of a secondary battery module without requiring processing the secondary battery module for observation unlike a technique for observing a cross section of an electrode using a scanning electron microscope (SEM). For this reason, X-ray analysis is widely used as the technique for observing an electrode state of a secondary battery module (for example, Patent Document 1). An X-ray analysis system disclosed in Patent Document 1 includes a sample switching device that positions, in a switchable manner, laminate cells (secondary battery modules) at a location through which an X-ray passes. In the X-ray analysis system disclosed in Patent Document 1, the sample switching device positions, in a switchable manner, laminate cells at a location through which an X-ray passes, so that the X-ray analysis of a plurality of the laminate cells can be efficiently performed.

Patent Document 1: Japanese Unexamined Patent Application, Publication No. 2015-232546

### SUMMARY OF THE INVENTION

In the case of a large-scale secondary battery module, the electrode state of the secondary battery module may vary in a plane of the secondary battery module. However, the X-ray analysis system disclosed in Patent Document 1 observes the electrode state only at one point fixed in the plane of the secondary battery module. Accordingly, in a case where variations occur in the plane of the secondary battery module, there is a possibility that the X-ray analysis system disclosed in Patent Document 1 cannot appropriately observe the electrode state.

In order to solve the above-described problem, the present invention has an object to provide an X-ray analysis system that enables appropriate observation of an electrode state.

(1) An X-ray analysis system according to the present invention obtains analysis data by irradiating, with an X-ray, a battery cell including a battery and a laminate housing the battery. The X-ray analysis system includes a sample holder that is configured to hold the sample holder and is able to restrain the battery cell, a holder that is able to switch an irradiation position indicating a position to be irradiated with the X-ray, with respect to the battery cell restrained by the sample holder, and a charger- discharger that charges and discharges the battery cell restrained by the sample holder. The sample holder includes a transmissive portion that allows the X-ray to be transmitted through a plurality points of the battery cell.

(2) In the X-ray analysis system described in the above (1), the transmissive portion may include a plurality of point-shaped partial transmissive portions.

(3) In the X-ray analysis system described in the above (1), the transmissive portion may have a corrugated shape.

(4) In the X-ray analysis system described in the above (1) or (2), the sample holder may include a first restraining member that is irradiated with the X-ray and is provided with the transmissive portion, a second restraining member that is irradiated with the X-ray transmitted through the first restraining member, and a cushion member that is arranged between the first restraining member and the battery cell, and the sample holder may restrain the battery cell while sandwiching the battery cell from opposite sides of the battery cell between the first restraining member and the second restraining member.

(5) In the X-ray analysis system described in the above (4), the first restraining member may include a portion to be irradiated with an X-ray that is irradiated with the X-ray in an irradiation direction, the first restraining member may include a thick portion, and a thin portion having a smaller length along the irradiation direction than the thick portion, and the transmissive portion may be provided in the thin portion.

(6) In the X-ray analysis system described in the above (4), the second restraining member may include an additional transmissive portion that transmits the X-ray transmitted through the transmissive portion, the transmissive portion may be a gap formed in the first restraining member, the additional transmissive portion may be a gap formed in the second restraining member, and the transmissive portion may have a smaller width than the additional transmissive portion.

(7) In the X-ray analysis system described in the above (4), the first restraining member may include a portion to be irradiated with an X-ray that is irradiated with the X-ray in an irradiation direction, the second restraining member may include an additional transmissive portion that transmits the X-ray transmitted through the transmissive portion, the additional transmissive portion may be a gap formed in the second restraining member, and the gap formed in the second restraining member may have a width that increase as a distance from the first restraining member increases, when viewed in the irradiation direction.

(8) In the X-ray analysis system described in the above (1) or (2), the X-ray analysis system may further include a detector that detects the X-ray transmitted through the sample holder and acquires X-ray analysis data The holder may switch the irradiation position to a plurality of points, and the charger-discharger may charge and discharge the battery cell in an identical pattern from an identical state of charge for each of the plurality of points, so that the detector may detect the X-ray that is transmitted through the sample holder for each of the plurality of points and acquire an electrode state distribution during charge and discharge.

According to the above-described (1), the sample holder includes the transmissive portion. The transmissive portion allows the X-ray to be transmitted through each of a plurality of points of the battery cell. This makes it possible to analyze the X-ray emitted to and transmitted through each of the plurality of points in the plane of the battery cell. As a result, even when varying depending on each place in the plane of the battery cell, the electrode state (for example, the SOC) can be appropriately observed. This makes it possible to appropriately observe the electrode state distribution in the plane of the battery cell during charge and discharge.

According to the above-described (2), the transmissive portion includes a plurality of point-shaped partial transmissive portions. Accordingly, the transmissive portion can be provided only where needed. For example, in a case where the transmissive portion includes holes provided in the first restraining member, the number of holes can be reduced. This makes it possible to improve the strength and rigidity of the first restraining member.

According to the above-described (3), the transmissive portion 270 has a corrugated shape. Accordingly, the transmissive portion allows the X-ray to be transmitted through each of the plurality of points of the battery cell over a wide range of the battery cell in a lateral direction and a longitudinal direction. This makes it possible to observe the electrode state over a wide range in the plane of the battery cell. As a result, the electrode state can be appropriately observed.

According to the above-described (4), in a case where the transmissive portion is a gap, a force applied to the battery cell may vary in the plane. However, in the sample holder, the cushion member is arranged between the first restraining member and the battery cell.

This makes it possible to equalize the force applied to the battery cell.

According to the above-described (5), the transmissive portion is provided in the thin portion. This makes it possible to improve the strength and rigidity of the first restraining member while reducing the X-ray absorption in the first restraining member.

According to the above-described (6), the width of the transmissive portion is smaller than the width of the additional transmissive portion. That is, the width of the additional transmissive portion on the X-ray detection side is larger than the width of the transmissive portion on the X-ray irradiation side. This makes it possible to acquire the average electrode state in the width direction of the battery cell.

According to the above-described (7), the width of the additional transmissive portion increases as the distance from the first restraining member increases, when viewed from the first restraining member side. Accordingly, the additional transmissive portion has a larger width on the X-ray detection side than on the X-ray irradiation side.

According to the above-described (8), in the X-ray analysis system, the holder switches the irradiation position to a plurality of points, and the charger-discharger charges and discharges the battery cell in the identical pattern from the identical state of charge for each of the plurality of points, so that the detector detects the X-ray that is transmitted through the sample holder for each of the plurality of points. This makes it possible to analyze the X-ray emitted to and transmitted through each of the plurality of points in the plane of the battery cell. As a result, even when varying depending on each place in the plane of the battery cell, the electrode state (for example, the SOC) can be appropriately observed. This makes it possible to appropriately observe the electrode state distribution in the plane of the battery cell during charge and discharge.

### BRIEF DESCRIPTION OF THE DRAWINGS

FIG. 1 is a block diagram of an X-ray analysis system according to an embodiment of the preset invention;

FIG. 2 is a schematic exploded perspective view of a sample holder;

FIG. 3 is a schematic front view of the sample holder when viewed in an irradiation direction;

FIG. 4 is a schematic exploded front view of a first restraining member when viewed in the irradiation direction;

FIG. 5 is a schematic exploded front view of a second restraining member when viewed in the irradiation direction;

FIG. 6A is a schematic cross-sectional view taken along line XIA-XIA in FIG. 3;

FIG. 6B is a schematic cross-sectional view along line XIB-XIB in FIG. 3;

FIG. 7 is a schematic exploded perspective view of the sample holder;

FIG. 8A is a schematic front view of the sample holder when viewed in the -Z direction side:

FIG. 8B is a schematic back view of the sample holder when viewed in the +Z direction side;

FIG. 9 is a schematic cross-sectional view along line IX-IX in FIG. 8A;

FIG. 10 is a diagram showing an example of a simulation result of an in-plane distribution of an SOC of a battery cell; and

FIG. 11 is a diagram showing an example of an X-ray analysis result of the SOC of the battery cell.

### DETAILED DESCRIPTION OF THE INVENTION

### Embodiment 1

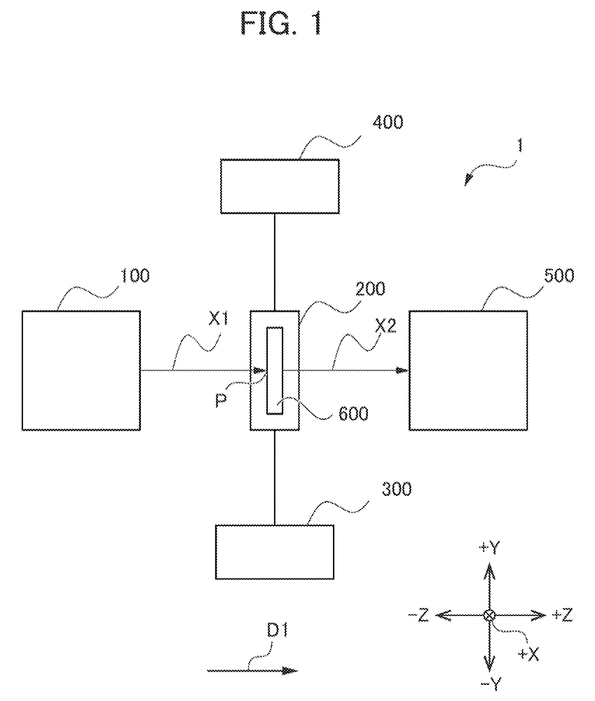

Each embodiment of the present invention will be described below with reference to the drawings. An X-ray analysis system 1 according to Embodiment 1 of the present invention will be described with reference to FIG. 1. FIG. 1 is a block diagram of the X-ray analysis system 1 according to an embodiment of the preset invention. In the following description, the X axis direction of the coordinates indicated in FIG. 1 may be referred to as a left-right direction (a direction of positive coordinates on the X axis as seen from the origin is a rightward direction), the Z axis direction of the coordinates indicated in FIG. 1 may be referred to as a front-rear direction (a direction of positive coordinates on the Y axis as seen from the origin is a forward direction), and the Y axis direction of the coordinates indicated in FIG. 1 (a direction perpendicular to an XZ plane) may be referred to as an up-down direction (a direction of positive coordinates on the Y axis as seen from the origin is an upward direction).

As illustrated in FIG. 1, the X-ray analysis system 1 includes an X-ray irradiator 100, a sample holder 200, a holder 300, a charger-discharger 400, and a detector 500. The X-ray analysis system 1 irradiates a battery cell 600 with an X-ray to obtain analysis data. The X-ray analysis system 1 obtains the analysis data by, for example, an in-situ X-ray diffraction (XRD) method or an in-situ X-ray absorption fine structure (XAFS) method.

The X-ray irradiator 100 emits an X-ray X1 toward the sample holder 200. That is, the X-ray irradiator 100 emits the X-ray X1 in an irradiation direction D1. The irradiation direction D1 is a direction from the -Z side to +Z side.

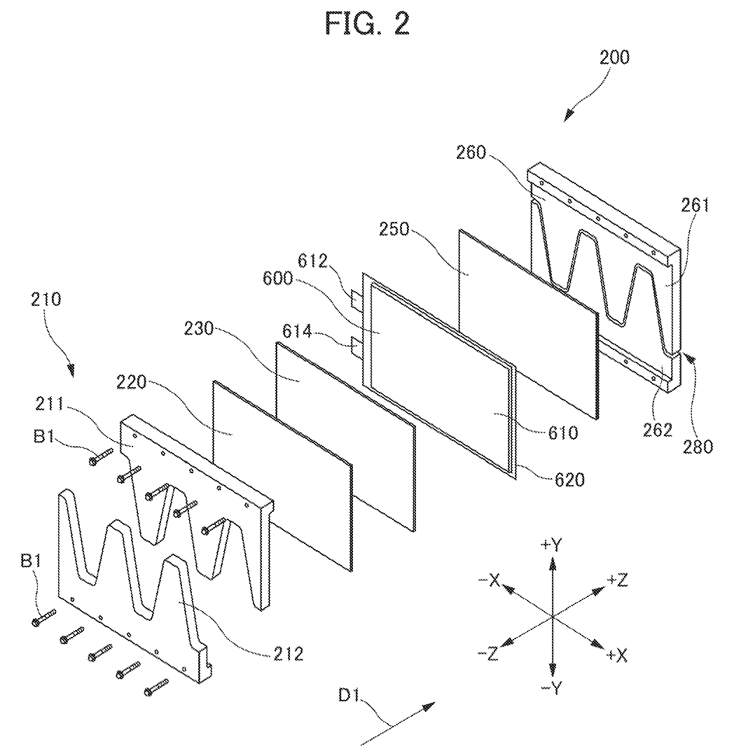

The sample holder 200 can restrain the battery cell 600. The details of the sample holder 200 will be described later with reference to FIG. 2 and the subsequent drawings.

The holder 300 holds the sample holder 200. The holder 300 can switch an irradiation position P. The irradiation position P indicates a position to be irradiated with the X-ray X1, with respect to the battery cell 600 restrained by the sample holder 200. The holder 300 is, for example, an actuator. The holder 300 moves the sample holder 200 in the X axis direction and the Y axis direction, to thereby switch the irradiation position P in a plane (in the XY plane) of the battery cell 600.

The charger-discharger 400 charges and discharges the battery cell 600 restrained by the sample holder 200. The charger-discharger 400 repeatedly charges and discharges the battery cell 600 within a predetermined period of time, for example. The charger-discharger 400 continues charge and discharge when the detector 500 detects an X-ray X2, for example. Alternatively, the charger-discharger 400 may stop the charge and discharge when the detector 500 detects the X-ray X2.

The detector 500 detects the X-ray X2 that is transmitted through the sample holder 200, and acquires data for the X-ray analysis. That is, the detector 500 detects the X-ray X2 that is transmitted through the battery cell 600 restrained by the sample holder 200, and acquires the data for the X-ray analysis.

In the X-ray analysis system 1, the holder 300 switches the irradiation position P to a plurality of points, and the charger-discharger 400 charges and discharges the battery cell in the same pattern from the same state of charge for each of the plurality of points P, so that the detector 500 detects the X-ray X2 that is transmitted through the sample holder 200 for each of the plurality of points P and acquires an electrode state distribution during charge and discharge. Accordingly, the electrode state can be appropriately observed.

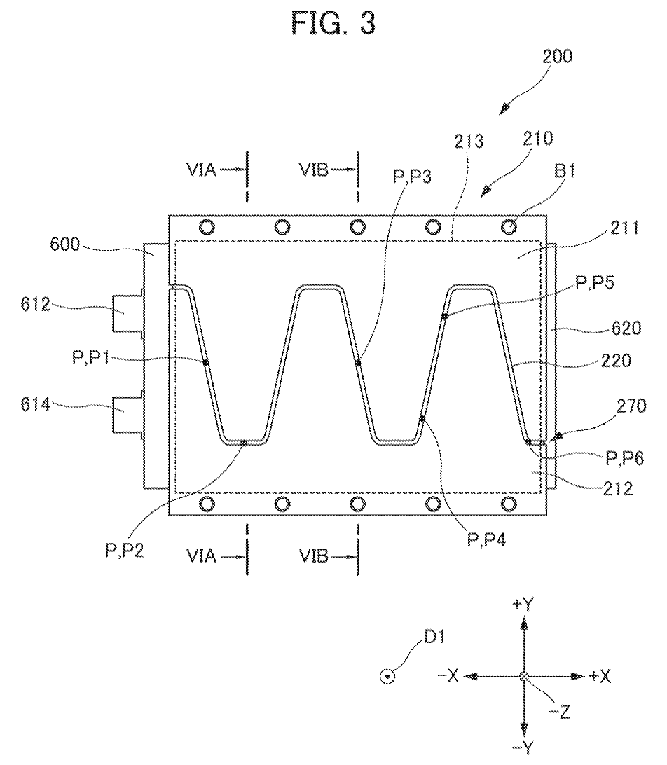

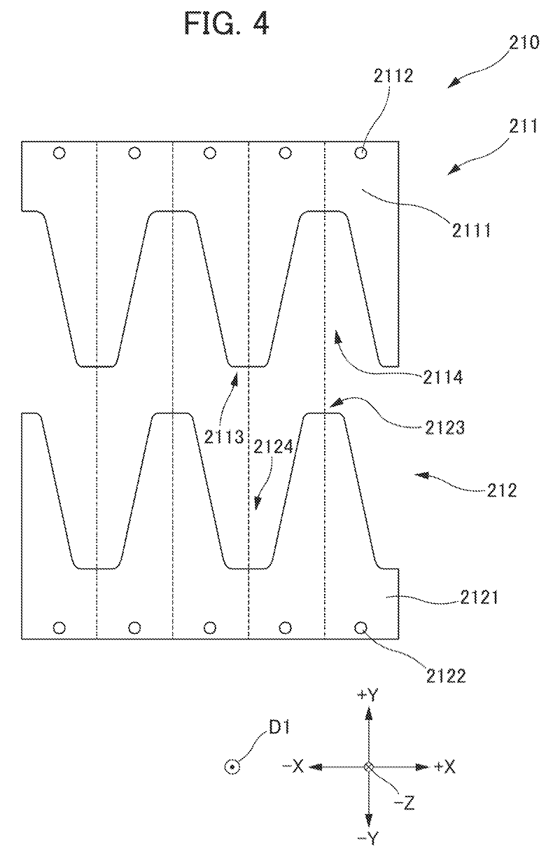

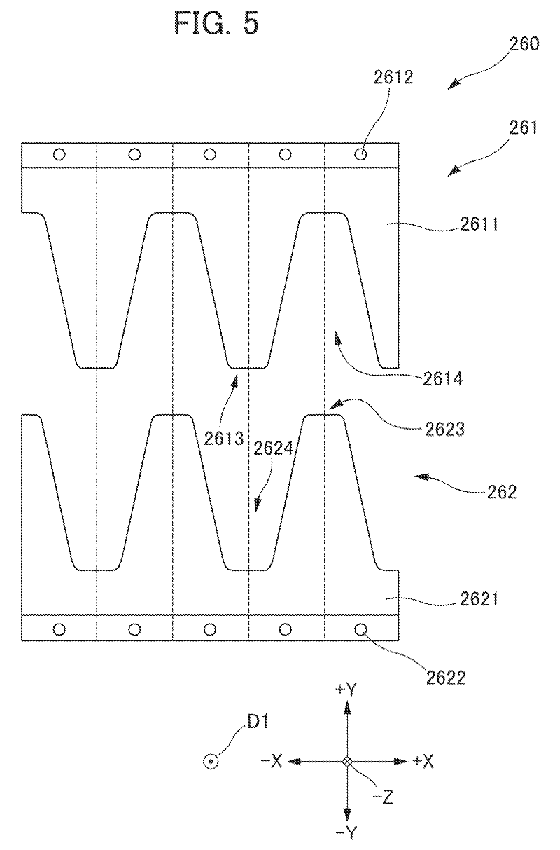

The sample holder 200 will be described with reference to FIGS. 1 to 5. FIG. 2 is a schematic exploded perspective view of the sample holder 200. FIG. 3 is a schematic front view of the sample holder 200 when viewed in the irradiation direction D1. FIG. 4 is a schematic exploded front view of a first restraining member 210 when viewed in the irradiation direction D1. FIG. 5 is a schematic exploded front view of a second restraining member 260 when viewed in the irradiation direction D1.

As illustrated in FIG. 2, the sample holder 200 includes the first restraining member 210, a cushion member 220, a first insulating member 230, a second insulating member 250, the second restraining member 260, a transmissive portion 270, and an additional transmissive portion 280. The first restraining member 210, the cushion member 220, the first insulating member 230, the second insulating member 250, and the second restraining member 260 are arranged in this order from the rear side (the -Z direction side). The sample holder 200 restrains the battery cell 600 while sandwiching the battery cell 600 from opposite sides of the battery cell 600 between the first restraining member 210 and the second restraining member 260.

The battery cell 600 includes a battery 610, and a laminate 620. The battery 610 is an all-solid lithium ion battery. The battery 610 includes a positive electrode terminal 612, a negative electrode terminal 614, and a solid electrolyte (not illustrated). The battery 610 is not limited to an all-solid lithium ion battery, and the electrolyte may be a liquid. The laminate 620 houses the battery 610. Specifically, the laminate 620 seals the battery 610.

The first restraining member 210 is located on one surface side (the -Z direction side) of the battery cell 600. The first restraining member 210 has, for example, a plate shape. The first restraining member 210 has a main surface formed into, for example, a rectangular shape. The first restraining member 210 is formed of a material that is not transmissive to the X-ray.

The first restraining member 210 is formed of, for example, a metal. The first restraining member 210 is irradiated with the X-ray X1.

As illustrated in FIGS. 3 and 4, the first restraining member 210 includes an upper member 211, and a lower member 212.

As illustrated in FIG. 3, the first restraining member 210 includes a portion to be irradiated with an X-ray 213. The portion to be irradiated with an X-ray 213 indicates a portion that can be irradiated with an X-ray. As illustrated in FIG. 4, the upper member 211 includes an upper main body 2111, upper projections 2113, and upper recesses 2114.

Upper through holes 2112 are formed in the upper main body 2111. Each of the upper through holes 2112 is a hole piercing the upper main body 2111 in the thickness direction (the Z axis direction). A bolt B1 (see FIG. 2) is inserted into each of the upper through holes 2112. Each of the upper projections 2113 is a portion projecting from the upper main body 2111. Each of the upper recesses 2114 is a portion further recessed than the upper projections 2113.

The lower member 212 includes an lower main body 2121, lower projections 2123, and lower recesses 2124. Lower through holes 2122 are formed in the lower main body 2121. Each of the lower through holes 2122 is a hole piercing the lower main body 2121 in the thickness direction (the Z axis direction). A bolt B1 (see FIG. 2) is inserted into each of the lower through holes 2122. Each of the lower projections 2123 is a portion projecting from the lower main body 2121. Each of the lower recesses 2124 is a portion further recessed than the lower projections 2123.

As illustrated in FIG. 3, the upper member 211 and the lower member 212 are arranged to face each other in the Y axis direction at an interval (gap) in the Y axis direction. Specifically, the upper member 211 and the lower member 212 are arranged so that the upper projections 2113 and the lower recesses 2124 face each other in the Y axis direction. More specifically, the upper member 211 and the lower member 212 are arranged so that the lower projections 2123 and the upper recesses 2114 face each other in the Y axis direction.

Reference will again be made to FIG. 2. The cushion member 220 is arranged between the first restraining member 210 and the battery cell 600. The cushion member 220 has, for example, a plate shape. The cushion member 220 has a main surface formed into, for example, a rectangular shape. The cushion member 220 is formed of, for example, urethane foam.

The first insulating member 230 is located on one surface side (the -Z direction side) of the battery cell 600. The first insulating member 230 has a main surface formed into, for example, a rectangular shape. The first insulating member 230 has, for example, a rectangular shape. The first insulating member 230 is formed of an insulating material. The first insulating member 230 is formed of, for example, a resin. The first insulating member 230 is formed of a material that is transmissive to the X-ray. The first insulating member 230 is transmissive to the X-ray emitted from the X-ray irradiator 100 (see FIG. 1), for example.

The second insulating member 250 is located on the other surface side (the +Z direction side) of the battery cell 600. The second insulating member 250 has, for example, a plate shape. The second insulating member 250 has a main surface formed into, for example, a rectangular shape. The second insulating member 250 is formed of an insulating material. The second insulating member 250 is formed of, for example, a resin. The second insulating member 250 is formed of a material that is transmissive to the X-ray. The second insulating member 250 is transmissive to the X-ray transmitted through the battery cell 600, for example.

The second restraining member 260 is located on the other surface side (the +Z direction side) of the battery cell 600. The second restraining member 260 has, for example, a plate shape.

The second restraining member 260 has a main surface formed into, for example, a rectangular shape. The second restraining member 260 is formed of a material that is not transmissive to the X-ray. The second restraining member 260 is formed of, for example, a metal. The second restraining member 260 is irradiated with the X-ray transmitted through the first restraining member 210.

The second restraining member 260 includes an upper member 261 and a lower member 262. As illustrated in FIG. 5, the upper member 261 includes an upper main body 2611, upper projections 2613, and upper recesses 2614.

Upper through holes 2612 are formed in the upper main body 2611. Each of the upper through holes 2612 is a hole piercing the upper main body 2611 in the thickness direction (the Z axis direction). A bolt B1 (see FIG. 2) is inserted into each of the upper through holes 2612. Each of the upper projections 2613 is a portion projecting from the upper main body 2611. Each of the upper recesses 2614 is a portion further recessed than the upper projections 2613.

The lower member 262 includes an lower main body 2621, lower projections 2623, and lower recesses 2624. Lower through holes 2622 are formed in the lower main body 2621. Each of the lower through holes 2622 is a hole piercing the lower main body 2621 in the thickness direction (the Z axis direction). A bolt B1 (see FIG. 2) is inserted into each of the lower through holes 2622. Each of the lower projections 2623 is a portion projecting from the lower main body 2621. Each of the lower recesses 2624 is a portion further recessed than the lower projections 2623.

The transmissive portion 270 transmits the X-ray. Specifically, the transmissive portion 270 transmits, for example, the X-ray X1 emitted from the X-ray irradiator 100. As illustrated in FIG. 3, in the present embodiment, the transmissive portion 270 is provided in the first restraining member 210. In the present embodiment, the transmissive portion 270 is a gap formed in the first restraining member 210. Alternatively, the transmissive portion 270 may be provided by sealing a gap formed in the first restraining member 210 with a material that is unlikely to absorb the X-ray, instead of being provided by the gap formed in the first restraining member 210. For example, the transmissive portion 270 may be provided by sealing the gap formed in the first restraining member 210 with carbon. In the present embodiment, the transmissive portion 270 has a corrugated shape. The transmissive portion 270 allows the X-ray to be transmitted through each of a plurality of points P of the battery cell 600. A point P1, a point P2, a point P3, a point P4, and a point P5 are examples of the plurality of points P. The plurality of points P can be set in a region corresponding to the transmissive portion 270. Therefore, the state of the battery cell 600 can be observed at each of the plurality of points P. Accordingly, the electrode state in the plane of the battery cell 600 can be observed. As a result, the electrode state can be appropriately observed. In addition, in the present embodiment, the transmissive portion 270 has a corrugated shape. Accordingly, the transmissive portion 270 allows the X-ray to be transmitted through each of the plurality of points P of the battery cell 600 over a wide range of the battery cell 600 in a lateral direction (the X axis direction) and a longitudinal direction (the Y axis direction). This makes it possible to observe the electrode state over a wide range in the plane of the battery cell 600. As a result, the electrode state can be appropriately observed. In the present embodiment, the width (the width of the gap between the upper member 211 and the lower member 212) of the transmissive portion 270 is constant. Alternatively, the width of the transmissive portion 270 may vary partially.

The additional transmissive portion 280 transmits the X-ray. Specifically, the additional transmissive portion 280 transmits the X-ray transmitted through the transmissive portion 270, for example. In the present embodiment, the additional transmissive portion 280 is provided in the second restraining member 260. In the present embodiment, the additional transmissive portion 280 is a gap formed in the second restraining member 260. Alternatively, the additional transmissive portion 280 may be provided by sealing a gap formed in the second restraining member 260 with a material that is unlikely to absorb the X-ray, instead of being provided by the gap formed in the second restraining member 260. For example, the additional transmissive portion 280 may be provided by sealing the gap formed in the second restraining member 260 with carbon. In the present embodiment, the additional transmissive portion 280 has a corrugated shape. The X-ray X2 transmitted through the additional transmissive portion 280, that is, the X-ray X2 transmitted through the sample holder 200 via the battery cell 600 reaches the detector 500 (see FIG. 1). Accordingly, the detector 500 detects the X-ray X2 to thereby acquire data for the X-ray analysis. As a result, the electrode state can be observed at each of the plurality of points P in the plane of the battery cell 600. Therefore, the electrode state can be appropriately observed. In addition, in the present embodiment, the additional transmissive portion 280 has a corrugated shape. Accordingly, the additional transmissive portion 280 allows the X-ray to be transmitted through each of the plurality of points P of the battery cell 600 over a wide range of the battery cell 600 in a lateral direction (the X axis direction) and a longitudinal direction (the Y axis direction). This makes it possible to observe the electrode state over a wide range in the plane of the battery cell 600. As a result, the electrode state can be appropriately observed. In the present embodiment, the width (the width of the gap between the upper member 261 and the lower member 262) of the additional transmissive portion 280 is constant. Alternatively, the width of the additional transmissive portion 280 may vary partially.

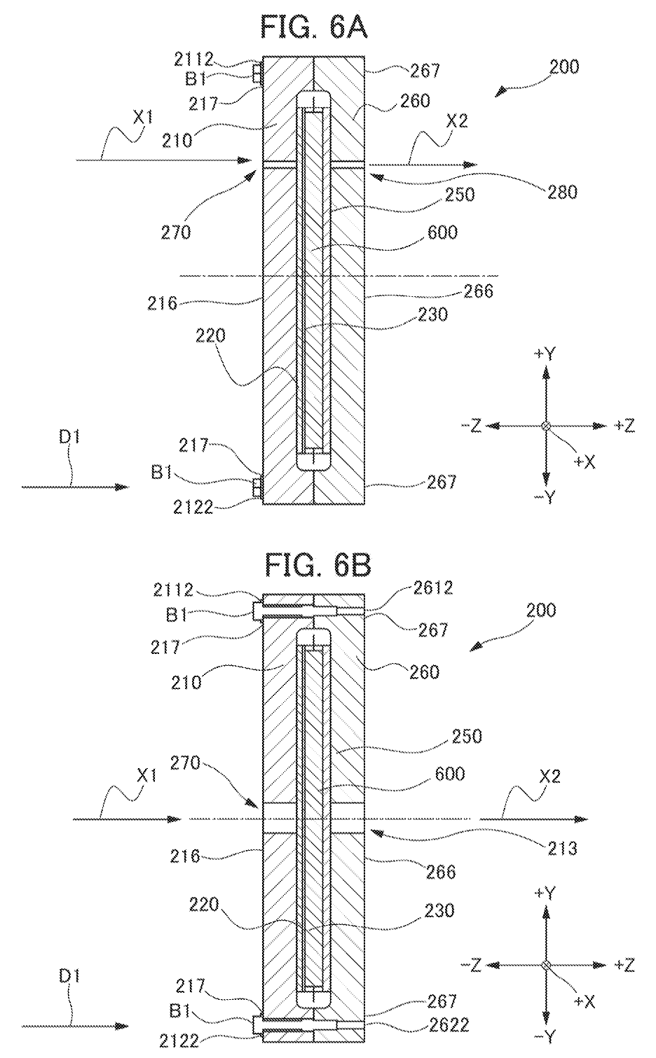

The sample holder 200 will be further described with reference to FIGS. 6A and 6B. FIG. 6A is a schematic cross-sectional view taken along line XIA-XIA in FIG. 3. FIG. 6B is a schematic cross-sectional view along line XIB-XIB in FIG. 3.

As illustrated in FIGS. 6A and 6B, the first restraining member 210 includes a thick portion 216, and a thin portion 217. The thin portion 217 has a smaller thickness than the thick portion 216. The transmissive portion 270 is provided in the thin portion 217. The upper through holes 2112 (see FIG. 4) and the lower through holes 2122 (see FIG. 4) are formed in the thick portion 216.

The second restraining member 260 includes a thick portion 266, and a thin portion 267. The thin portion 267 has a smaller thickness than the thick portion 266. The additional transmissive portion 280 is provided in the thin portion 267. The upper through holes 2612 (see FIG. 5) and the lower through holes 2622 (see FIG. 5) are formed in the thick portion 266.

In the present embodiment, the width (the length along the Y axis direction) of the transmissive portion 270 is the same as the width (the length along the Y axis direction) of the additional transmissive portion 280. Alternatively, the width of the transmissive portion 270 may be different from the width of the additional transmissive portion 280. In this case, the width of the transmissive portion 270 is preferably smaller than the width of the additional transmissive portion 280. Since the additional transmissive portion 280 is arranged at a position corresponding to the transmissive portion 270, the X-ray X1 emitted from the X-ray irradiator 100 is transmitted through the transmissive portion 270, and is transmitted through the additional transmissive portion 280 via the battery cell 600, and the X-ray X2 reaches the detector 500.

As described above with reference to FIGS. 1 to 6, in the X-ray analysis system 1 according to the present embodiment, the sample holder 200 includes the transmissive portion 270. The transmissive portion 270 allows the X-ray to be transmitted through each of the plurality of points P of the battery cell 600. This makes it possible to analyze the X-ray emitted to and transmitted through each of the plurality of points P in the plane of the battery cell 600. As a result, even when varying depending on each place in the plane of the battery cell 600, the electrode state (for example, the SOC) can be appropriately observed. This makes it possible to appropriately observe the electrode state distribution in the plane of the battery cell 600 during charge and discharge.

The transmissive portion 270 has a corrugated shape. Accordingly, the transmissive portion 270 allows the X-ray to be transmitted through each of the plurality of points P of the battery cell 600 over a wide range of the battery cell 600 in a lateral direction (the X axis direction) and a longitudinal direction (the Y axis direction). This makes it possible to observe the electrode state over a wide range in the plane of the battery cell 600. As a result, the electrode state can be appropriately observed.

In a case where the transmissive portion 270 is a gap, a force applied to the battery cell 600 may vary in the plane. However, in the sample holder 200, the cushion member 220 is arranged between the first restraining member 210 and the battery cell 600. This makes it possible to equalize the force applied to the battery cell 600.

The transmissive portion 270 is provided in the thin portion 217. This makes it possible to improve the strength and rigidity of the first restraining member 210 while reducing the X-ray absorption in the first restraining member 210.

In the X-ray analysis system 1, the holder 300 switches the irradiation position P to a plurality of points, and the charger-discharger 400 charges and discharges the battery cell 600 in the same pattern from the same state of charge for each of the plurality of points P, so that the detector 500 detects the X-ray X2 that is transmitted through the sample holder 200 for each of the plurality of points P. This makes it possible to analyze the X-ray emitted to and transmitted through each of the plurality of points P in the plane of the battery cell 600. As a result, even when varying depending on each place in the plane of the battery cell 600, the electrode state (for example, the SOC) can be appropriately observed. This makes it possible to appropriately observe the electrode state distribution in the plane of the battery cell 600 during charge and discharge.

### [Embodiment 2]

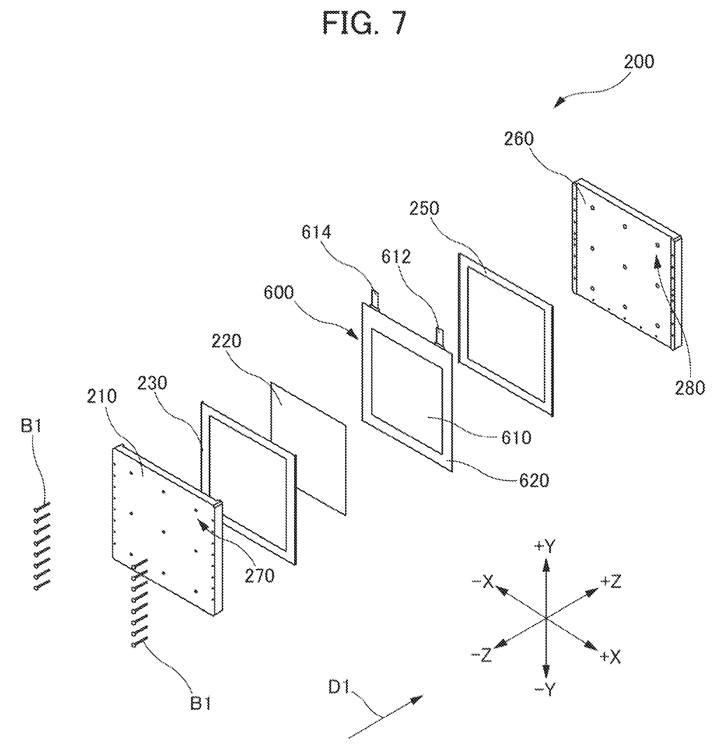

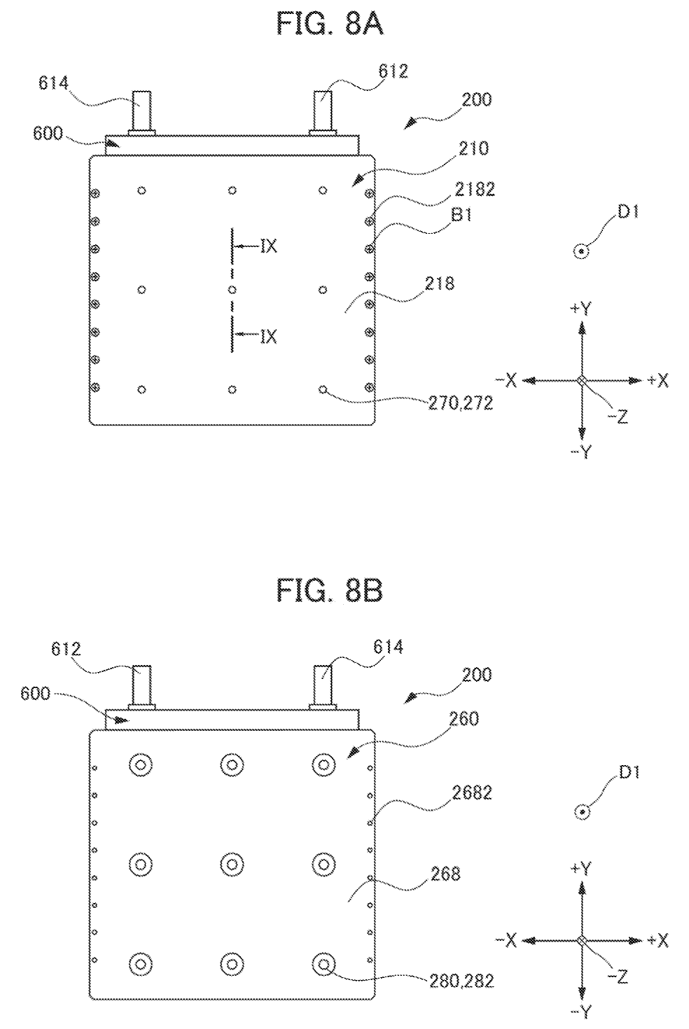

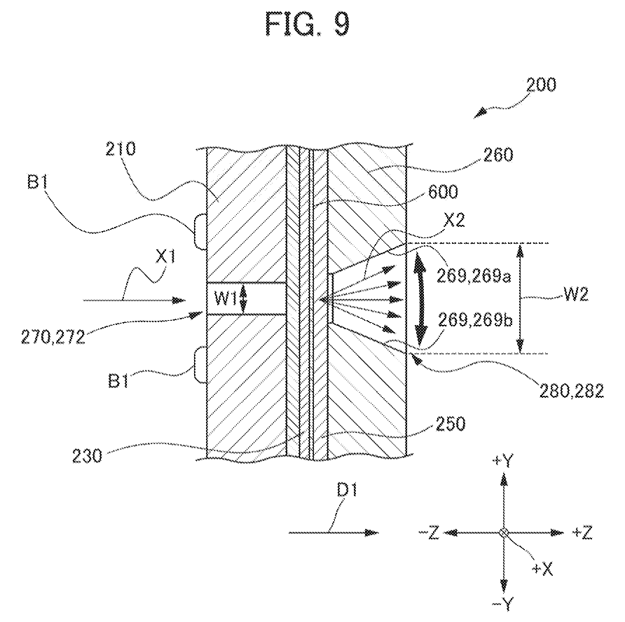

An X-ray analysis system 1 according to Embodiment 2 of the present invention will be described with reference to FIGS. 7 to 9. FIG. 7 is a schematic exploded perspective view of a sample holder 200 according to Embodiment 2 of the present invention. FIG. 8A is a schematic front view of the sample holder 200 when viewed in the -Z direction side. FIG. 8B is a schematic back view of the sample holder 200 when viewed in the +Z direction side. FIG. 9 is a schematic cross-sectional view along line IX-IX in FIG. 8A. The X-ray analysis system 1 according to Embodiment 2 is different from the X-ray analysis system 1 according to Embodiment 1 in that the transmissive portion 270 and the additional transmissive portion 280 are different. Embodiment 2 will be described below while focusing mainly on the difference from Embodiment 1.

As illustrated in FIG. 7, the sample holder 200 includes a first restraining member 210, a cushion member 220, a first insulating member 230, a second insulating member 250, a second restraining member 260, a transmissive portion 270, and an additional transmissive portion 280. In Embodiment 2, the arrangement of the cushion member 220 and the first insulating member 230 is different from that in Embodiment 1.

As illustrated in FIG. 8A, the first restraining member 210 includes a main body 218. Through holes 2182 are formed in the main body 218. Each of the through holes 2182 is a hole piercing the main body 218 in the thickness direction (the Z axis direction). A bolt B1 is inserted into each of the through holes 2182. The transmissive portion 270 is provided in the first restraining member 210. In the present embodiment, the transmissive portion 270 includes a plurality of partial transmissive portions 272. In the present embodiment, the transmissive portion 270 includes the nine partial transmissive portions 272. The nine partial transmissive portions 272 are arranged at intervals in the X axis direction and the Y axis direction. In the present embodiment, the nine partial transmissive portions 272 are arranged in a matrix of three in the X axis direction and three in the Y axis direction. Each of the plurality of partial transmissive portions 272 has a point shape. The plurality of partial transmissive portions 272 are provided in the first restraining member 210. Each of the plurality of partial transmissive portions 272 is a hole piercing the main body 218 in the thickness direction (the Z axis direction).

As illustrated in FIG. 8B, the second restraining member 260 includes a main body 268. Through holes 2682 are formed in the main body 268. Each of the through holes 2682 is a hole piercing the main body 268 in the thickness direction (the Z axis direction). A bolt B1 is inserted into each of the through holes 2682. The additional transmissive portion 280 is provided in the second restraining member 260. The additional transmissive portion 280 includes a plurality of partial additional transmissive portions 282. In the present embodiment, the additional transmissive portion 280 includes the nine partial additional transmissive portions 282. The nine partial additional transmissive portions 282 are arranged at intervals in the X axis direction and the Y axis direction. In the present embodiment, the nine partial additional transmissive portions 282 are arranged in a matrix of three in the X axis direction and three in the Y axis direction. In the present embodiment, each of the plurality of partial additional transmissive portions 282 has a point shape. The plurality of partial additional transmissive portions 282 are provided in the second restraining member 260. Each of the plurality of partial additional transmissive portions 282 is a hole piercing the main body 218 in the thickness direction (the Z axis direction).

As illustrated in FIG. 9, a width W1 (the length along the Y axis direction) of the transmissive portion 270 is smaller than a width W2 (the length along the Y axis direction) of the additional transmissive portion 280. The width of the additional transmissive portion 280 increases as the distance from the first restraining member 210 increases, when viewed from the first restraining member 210 side. The second restraining member 260 includes a wall surface 269. The wall surface 269 forms the partial transmissive portion 272. The wall surface 269 is inclined with respect to the Z axis. Specifically, a wall surface 269a is inclined in the +Y direction with respect to the Z axis. A wall surface 269b is inclined in the -Y direction with respect to the Z axis.

As described above with reference to FIGS. 7 to 9, in the X-ray analysis system 1 according to the present embodiment, the transmissive portion 270 includes a plurality of point-shaped partial transmissive portions 272. Accordingly, the transmissive portion 270 can be provided only where needed. For example, in a case where the transmissive portion 270 includes holes provided in the first restraining member 210, the number of holes can be reduced. This makes it possible to improve the strength and rigidity of the first restraining member 210.

The width W1 (the length along the Y axis direction) of the transmissive portion 270 is smaller than the width W2 (the length along the Y axis direction) of the additional transmissive portion 280. That is, the width W2 of the additional transmissive portion 280 on the X-ray detection side is larger than the width W1 of the transmissive portion 270 on the X-ray irradiation side. This makes it possible to acquire the average electrode state in the width direction (the Y axis direction) of the battery cell 600.

The width W2 of the additional transmissive portion 280 increases as the distance from the first restraining member 210 increases, when viewed from the first restraining member 210 side. Accordingly, the additional transmissive portion 280 has a larger width on the X-ray detection side than on the X-ray irradiation side.

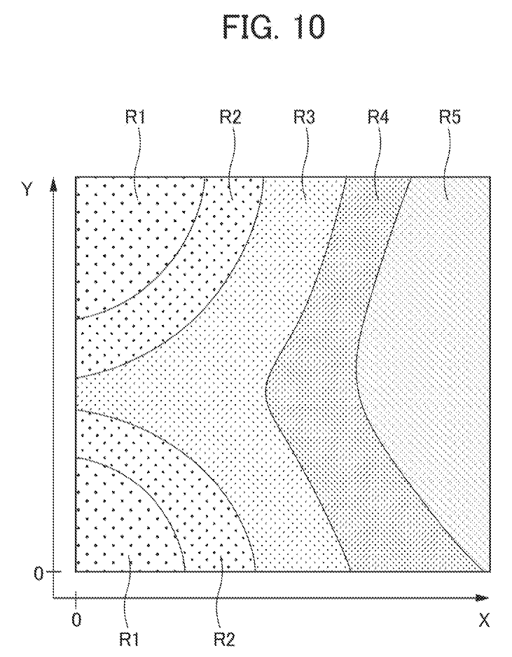

An example of a simulation result of an in-plane distribution of a state of charge (SOC) of the battery cell will be described with reference to FIG. 10. The SOC indicates a charge level of the battery cell. FIG. 10 is a diagram showing an example of a simulation result of an in-plane distribution of the SOC of the battery cell. In FIG. 10, the X axis and the Y axis indicate XY coordinates in the battery cell. In FIG. 10, the coordinates of X = 0, Y = 0 indicate the coordinates where a negative electrode terminal 614 is located. In FIG. 10, the coordinates of X = 0, Y = the maximum value indicate the coordinates where a positive electrode terminal 612 is located. In FIG. 10, each of regions R1 to R5 indicates a region in which the SOC values are substantially the same. In FIG. 10, the density of a dot pattern indicates an SOC value, and as the density of the dot pattern increases, the SOC increases. That is, in FIG. 10, the SOC satisfies the relationship of the region R1 < the region R2 < the region R3 < the region R4 < the region R5.

As illustrated in FIG. 10, in the regions close to X = 0, Y = 0 and X = 0, Y = the maximum value, the SOC is the lowest. As the coordinates deviate from X = 0, Y = 0, and X = 0, Y = the maximum value, the SOC gradually increases. That is, as the position deviates from the positive electrode terminal 612 and/or the negative electrode terminal 614, the SOC gradually increases. In other words, as the position deviates from the positive electrode terminal 612 and/or the negative electrode terminal 614, an increase in the SOC is shown with gradation. In FIG. 10, the SOC satisfies the relationship of the region R1 < the region R2 < the region R3 < the region R4 < the region R5. For ease of illustration, the region is divided into five so that each indicates a region in which the SOC values are substantially the same, but each of the region R1, the region R2, the region R3, the region R4, and the region R5 is shown with gradation so that the SOC increases as the position deviates from the positive electrode terminal 612 and/or the negative electrode terminal 614. In this way, in general, the SOC of a battery cell, in particular, the SOC of a large-scale battery cell tends to vary in the plane. Accordingly, it is preferable that the SOC of a battery cell, in particular, the SOC of a large-scale battery cell is measured at each of a plurality of points in the plane to thereby analysis the characteristics of the electrode state. The X-ray analysis system 1 according to an embodiment of the present invention can measure the electrode state at each of the plurality of points in the plane for the SOC of the battery cell.

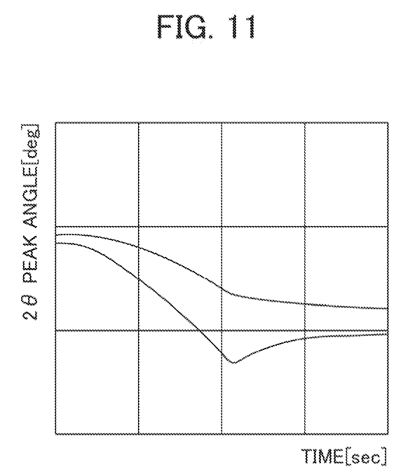

An example of an X-ray analysis result of the SOC of the battery cell will be described with reference to FIG. 11. FIG. 11 is a diagram showing an example of an X-ray analysis result of the SOC of the battery cell. Specifically, FIG. 11 is a diagram showing an example of an X-ray analysis result at each of a plurality of points in the plane for the SOC of the battery cell using the sample holder 200 illustrated in FIG. 2 in the X-ray analysis system (see FIG. 1) according to an embodiment of the present invention. In FIG. 11, the horizontal axis indicates time. In FIG. 11, the vertical axis indicates a diffraction angle 2θ at which an intensity peak of the X-ray is detected.

As illustrated in FIG. 11, the diffraction angles 2θ over time at which the intensity peaks of the X-ray measured at a plurality of points are detected differ at each measurement point. That is, it has been confirmed that the diffraction angles 2θ over time at which the measured intensity peaks of the X-ray are detected causes a difference at each position (XY coordinates) of the battery cell. Accordingly, it is preferable that for the SOC of a battery cell, in particular, the SOC of a large-scale battery cell, the diffraction angle 2θ at which the intensity peak of the X-ray is detected at each of a plurality of points in the plane is measured to thereby analysis the characteristics of the electrode state. The X-ray analysis system 1 according to an embodiment of the present invention can measure the electrode state at each of the plurality of points in the plane for the SOC of the battery cell.

According to the X-ray analysis system 1 according to the present embodiment, the following effects are obtained.

(1) In the X-ray analysis system 1, the sample holder 200 includes the transmissive portion 270. The transmissive portion 270 allows the X-ray to be transmitted through a plurality of points P of the battery cell 600. This makes it possible to analyze the X-ray emitted to and transmitted through each of the plurality of points P in the plane of the battery cell 600. As a result, even when varying depending on each place in the plane of the battery cell 600, the electrode state (for example, the SOC) can be appropriately observed. This makes it possible to appropriately observe the electrode state distribution in the plane of the battery cell 600 during charge and discharge.

(2) In the X-ray analysis system 1, the transmissive portion 270 includes a plurality of point-shaped partial transmissive portions 272. Accordingly, the transmissive portion 270 can be provided only where needed. For example, in a case where the transmissive portion 270 includes holes provided in the first restraining member 210, the number of holes can be reduced. This makes it possible to improve the strength and rigidity of the first restraining member 210.

(3) In the X-ray analysis system 1, the transmissive portion 270 has a corrugated shape. Accordingly, the transmissive portion 270 allows the X-ray to be transmitted through each of the plurality of points P of the battery cell 600 over a wide range of the battery cell 600 in a lateral direction (the X axis direction) and a longitudinal direction (the Y axis direction). This makes it possible to observe the electrode state over a wide range in the plane of the battery cell 600. As a result, the electrode state can be appropriately observed.

(4) In the X-ray analysis system 1, in a case where the transmissive portion 270 is a gap, a force applied to the battery cell 600 may vary in the plane. However, in the sample holder 200, the cushion member 220 is arranged between the first restraining member 210 and the battery cell 600. This makes it possible to equalize the force applied to the battery cell 600.

(5) In the X-ray analysis system 1, the transmissive portion 270 is provided in the thin portion 217. This makes it possible to improve the strength and rigidity of the first restraining member 210 while reducing the X-ray absorption in the first restraining member 210.

(6) In the X-ray analysis system 1, the width W1 (the length along the Y axis direction) of the transmissive portion 270 is smaller than the width W2 (the length along the Y axis direction) of the additional transmissive portion 280. That is, the width W2 of the additional transmissive portion 280 on the X-ray detection side is larger than the width W1 of the transmissive portion 270 on the X-ray irradiation side. This makes it possible to acquire the average electrode state in the width direction (the Y axis direction) of the battery cell 600.

(7) In the X-ray analysis system 1, the width W2 of the additional transmissive portion 280 increases as the distance from the first restraining member 210 increases, when viewed from the first restraining member 210 side. Accordingly, the additional transmissive portion 280 has a larger width on the X-ray detection side than on the X-ray irradiation side.

(8) In the X-ray analysis system 1, the holder 300 switches the irradiation position P to a plurality of points, and the charger-discharger 400 charges and discharges the battery cell 600 in the same pattern from the same state of charge for each of the plurality of points P, so that the detector 500 detects the X-ray X2 that is transmitted through the sample holder 200 for each of the plurality of points P. This makes it possible to analyze the X-ray emitted to and transmitted through each of the plurality of points P in the plane of the battery cell 600. As a result, even when varying depending on each place in the plane of the battery cell 600, the electrode state (for example, the SOC) can be appropriately observed. This makes it possible to appropriately observe the electrode state distribution in the plane of the battery cell 600 during charge and discharge.

Although embodiments of the present invention are described above, the present invention is not limited to the above-described embodiments, and various changes and modifications can be made.

What is claimed is:

1. An X-ray analysis system that obtains analysis data by irradiating, with an X-ray, a battery cell including a battery and a laminate housing the battery, the X-ray analysis system comprising:
a sample holder that is able to restrain the battery cell;
a holder that is configured to hold the sample holder and is able to switch an irradiation position indicating a position to be irradiated with the X-ray, with respect to the battery cell restrained by the sample holder; and
a charger-discharger that charges and discharges the battery cell restrained by the sample holder, wherein
the sample holder includes a transmissive portion that allows the X-ray to be transmitted through a plurality points of the battery cell.

2. The X-ray analysis system according to claim 1, wherein the transmissive portion includes a plurality of point-shaped partial transmissive portions.

3. The X-ray analysis system according to claim 1, wherein the transmissive portion has a corrugated shape.

4. The X-ray analysis system according to claim 1, wherein
the sample holder includes:
a first restraining member that is irradiated with the X-ray and is provided with the transmissive portion;
a second restraining member that is irradiated with the X-ray transmitted through the first restraining member; and
a cushion member that is arranged between the first restraining member and the battery cell, and
the sample holder restrains the battery cell while sandwiching the battery cell from opposite sides of the battery cell between the first restraining member and the second restraining member.

5. The X-ray analysis system according to claim 4, wherein
the first restraining member includes a portion to be irradiated with an X-ray that is irradiated with the X-ray in an irradiation direction,
the first restraining member includes:
a thick portion; and
a thin portion having a smaller length along the irradiation direction than the thick portion, and
the transmissive portion is provided in the thin portion.

6. The X-ray analysis system according to claim 4, wherein
the second restraining member includes an additional transmissive portion that transmits the X-ray transmitted through the transmissive portion,
the transmissive portion is a gap formed in the first restraining member,
the additional transmissive portion is a gap formed in the second restraining member, and
the transmissive portion has a smaller width than the additional transmissive portion.

7. The X-ray analysis system according to claim 4, wherein
the first restraining member includes a portion to be irradiated with an X-ray that is irradiated with the X-ray in an irradiation direction,
the second restraining member includes an additional transmissive portion that transmits the X-ray transmitted through the transmissive portion,
the additional transmissive portion is a gap formed in the second restraining member, and
the gap formed in the second restraining member has a width that increases as a distance from the first restraining member increases, when viewed in the irradiation direction.

8. The X-ray analysis system according to claim 1, further comprising
a detector that detects the X-ray transmitted through the sample holder and acquires X-ray analysis data, wherein
the holder switches the irradiation position to a plurality of points, and the charger-discharger charges and discharges the battery cell in an identical pattern from an identical state of charge for each of the plurality of points, so that the detector detects the X-ray that is transmitted through the sample holder for each of the plurality of points and acquires an electrode state distribution during charge and discharge.
